(19) United States
(12) Patent Application Publication
(10) Pub. No.: US 2007/0278613 A1
(43) Pub. Date: Dec. 6, 2007

(54) Semiconductor device

(76) Inventor: Masahiro Imade, Osaka (JP)

Correspondence Address: MCDERMOTT WILL & EMERY LLP, 600 13TH STREET, NW, WASHINGTON, DC, 20005-3096, US

(21) Appl. No.: 11/806,311

(22) Filed: May 31, 2007

(30) Foreign Application Priority Data
May 31, 2006 (JP) 2006-151605
Apr. 19, 2007 (JP) 2007-110657

(51) Int. Cl. H01L 29/00

(52) U.S. Cl. 257/500

(57) ABSTRACT

A semiconductor device includes: a semiconductor substrate; a device active portion formed in the semiconductor substrate; a device isolation portion formed in the semiconductor substrate so as to surround the periphery of the device active portion; an insulating film stacked on the device active portion; and a gate electrode stacked on the insulating film. The device active portion includes: a source region and a drain region located opposite each other in a gate length direction, and a channel region interposed between the source region and the drain region. The channel region includes: a central region connecting the source and drain regions and having an approximately rectangular shape, and a protruding region protruding from one side end of the central region in a gate width direction. The channel region is located inwardly of the gate electrode when viewed in the stacking direction.

### BACKGROUND OF THE INVENTION

1. Field of the Invention

The present invention relates to semiconductor devices, and more particularly relates to a semiconductor device including a device isolation portion formed using STI (shallow trench isolation).

2. Description of the Related Art

A semiconductor integrated circuit includes insulted-gate field-effect transistors (hereinafter referred to as “transistors”). In the semiconductor substrate, these transistors are electrically separated from each other by a device isolation portion. A method for forming such a device isolation portion is a device isolation method using STI (shallow trench isolation). A STI is formed by forming trenches in the semiconductor substrate and then filling the trenches with insulating material. STI, which allows the formation of a device isolation portion having a narrow isolation width, is a mainstream device-isolation method in recent microscaled fabrication processes.

However, in a semiconductor device fabricated using a STI device-isolation method, the transistor's threshold-voltage characteristics may degrade. Specifically, as shown in FIG. 13, the transistor shows characteristics (indicated by the solid line), called hump characteristics, in which off-leakage current is increased, rather than its original transistor characteristics (indicated by the broken line). The off-leakage current is thus increased as compared with the original transistor characteristics. This phenomenon occurs because the threshold voltage in parts located near the boundary between the STI and the channel region becomes lower than the threshold voltage in the central part of the channel region to cause those parts located near the boundary to operate as parasitic transistors.

One reason for the formation of the parasitic transistors is the cross-sectional shape of the boundary portion between the STI and the channel region. If the cross-sectional shape is angular as shown in FIG. 8 in Japanese Laid-Open Publication No. 2004-288873 (Patent Document 1), the electric field is concentrated in parts (100A and 100B) of the boundary portion between the STI and the substrate, causing the threshold voltage in those parts to be lowered. Another reason is a decrease in channel impurity concentration in the vicinity of the boundary portion between the STI and the channel region. Impurities introduced into the channel region diffuse into the STI during an annealing process performed in the semiconductor device fabrication process, resulting in a decrease in impurity concentration in the vicinity of the STI. The decreased impurity concentration leads to a decline in the threshold voltage in the vicinity of the boundary portion between the STI and the channel region.

In recent years, semiconductor devices have been required to reduce their power consumption for their applications to mobile devices. It is thus very important to suppress hump characteristics. Examples of methods typically adopted to prevent hump characteristics include a method, in which the concentration of electric field is reduced by rounding the cross-sectional shape of the boundary portion between the STI and the channel region, and a method, in which, in the step of forming the STI, impurities are introduced into the side faces of the trenches before the trenches are filled with insulating material, thereby preventing a decrease in impurity concentration in the vicinity of the STI.

Another hump-characteristics-prevention method is to construct a transistor in such a manner that no parasitic transistor is formed at the boundary portion between the STI and the channel region (as shown in FIGS. 1, 5, etc. in Patent Document 1, for example). In the transistor shown in Patent Document 1, a region (a semiconductor region 1A₋₂) over which no gate electrode is present is formed at the boundary portion between the STI and the channel region. This semiconductor region exhibits a conductivity type that is opposite to that of the source and drain regions. For instance, if the source and drain regions are n-type semiconductors, the semiconductor region is a p-type semiconductor. No parasitic transistor is thus formed at the boundary portion between the STI and the channel region, such that hump characteristics do not appear.

Typically, in n-type transistor fabrication process, after a gate electrode is formed, n-type impurities are heavily introduced into regions including parts that are to be source and drain regions and the gate electrode, whereby the source and drain regions are formed.

However, in the transistor described in Patent Document 1, when n-type impurities are heavily introduced, it is necessary to cover and protect the region that is to be the semiconductor region so as to form the semiconductor region that exhibits a conductivity type opposite to that of the source and drain regions. According to Patent Document 1, the size of the semiconductor region is as small as the minimum feature size of lithography. It is very difficult to cover such a microscopic region with high accuracy.

### SUMMARY OF THE INVENTION

It is therefore an object of the present invention to provide a semiconductor device in which hump characteristics are suppressed and which can be fabricated in an easier manner than conventional semiconductor devices.

In one aspect of the present invention, a semiconductor device includes a semiconductor substrate, a device active portion, a device isolation portion, an insulating film, and a gate electrode. The device active portion is formed in the principal surface of the semiconductor substrate. The device isolation portion is formed in the principal surface of the semiconductor substrate so as to surround the periphery of the device active portion. The insulating film is stacked on the device active portion. The gate electrode is stacked on the insulating film. The device active portion includes a source region, a drain region, and a channel region. The source region and the drain region are located opposite each other in a gate length direction. The channel region is interposed between the source region and the drain region and exhibits a conductivity type different from that of the source and drain regions. The channel region includes a central region and a protruding region. The central region connects the source and drain regions and has an approximately rectangular shape. The protruding region protrudes from one side end of the central region in a gate width direction. The channel region is located inwardly of the gate electrode when viewed in the stacking direction.

In the semiconductor device described above, since the channel length of a parasitic transistor (the length of a subchannel) and hence the resistance of the parasitic transistor are increased, it is possible to reduce off-leakage current passing thorough the parasitic transistor. This allows hump characteristics to be suppressed. Furthermore, the channel region is located inwardly of the gate electrode when viewed in the stacking direction. Thus, unlike in the conventional case, it is not necessary to cover and protect a specific region, allowing the semiconductor device to be fabricated in an easier manner as compared with conventional semiconductor devices.

In another aspect of the present invention, a semiconductor device includes a semiconductor substrate, a device active portion, a device isolation portion, an insulating film, and a gate electrode. The device active portion is formed in the principal surface of the semiconductor substrate. The device isolation portion is formed in the principal surface of the semiconductor substrate so as to surround the periphery of the device active portion. The insulating film is stacked on the device active portion. The gate electrode is stacked on the insulating film. The device active portion includes a source region, a drain region, and a channel region. The source region and the drain region are located opposite each other in a gate length direction. The channel region is interposed between the source region and the drain region and exhibits a conductivity type different from that of the source and drain regions. The channel region includes a central region and a recessed region. The central region connects the source and drain regions and has an approximately rectangular shape. The recessed region recesses from one side end of the central region toward inside the central region in a gate width direction. The channel region is located inwardly of the gate electrode when viewed in the stacking direction.

### BRIEF DESCRIPTION OF THE DRAWINGS

FIG. 1A is a plan view illustrating a semiconductor device according to an embodiment of the present invention.

FIG. 1B is a cross-sectional view of the semiconductor device taken along the line Ib-Ib in FIG. 1A.

FIG. 1C is a cross-sectional view of the semiconductor device taken along the line Ic-Ic in FIG. 1A.

FIG. 1D is a cross-sectional view of the semiconductor device taken along the line Id-Id in FIG. 1A.

FIG. 2 is a graph indicating relationship between the extended width of a channel region and off-leakage characteristics.

FIG. 3 is a plan view illustrating an exemplary layout in which a single common gate electrode is disposed over a plurality of device active portions.

FIG. 4 is a plan view for explaining the base end width of a protruding region.

FIG. 5 is a plan view for explaining the shape of the protruding region.

FIG. 6 is another plan view for explaining the shape of the protruding region.

FIG. 7 is another plan view for explaining the shape of the protruding region.

FIG. 8 is a plan view for explaining the shape of source and drain regions.

FIG. 9 is another plan view for explaining the shape of the source and drain regions.

FIG. 10 is a plan view for explaining an extended region.

FIG. 11 is another plan view for explaining the extended region.

FIG. 12 is a plan view for explaining recessed regions.

FIG. 13 is a graph for explaining hump characteristics.

### DETAILED DESCRIPTION OF THE INVENTION

Hereinafter, embodiments of the present invention will be described in detail with reference to the accompanying drawings.

### First Embodiment

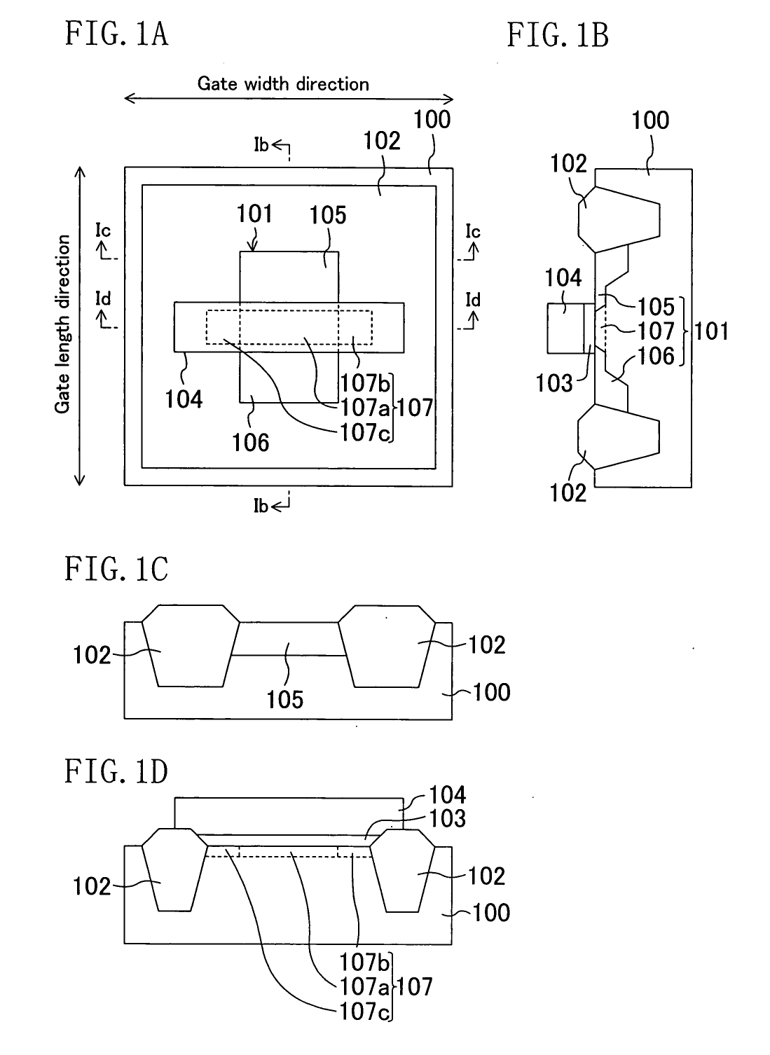

FIG. 1A is a plan view illustrating a semiconductor device according to a first embodiment of the present invention. FIGS. 1B, 1C, and 1D are cross-sectional views of the semiconductor device taken along the lines Ib-Ib, Ic-Ic, and Id-Id, respectively, in FIG. 1A.

The semiconductor device includes a semiconductor substrate 100, a device active portion 101, a device isolation portion 102, a gate insulating film 103, and a gate electrode 104.

The device active portion 101 is formed in the principal surface of the semiconductor substrate 100. The device isolation portion 102, which is a STI (shallow trench isolation), for example, is formed in the principal surface of the semiconductor substrate 100 so as to surround the periphery of the device active portion 101. The gate electrode 104 is stacked over the device active portion 101 with the gate insulating film 103 interposed therebetween.

The device active portion 101 includes a source region 105, a drain region 106, and a channel region 107. The source region 105 and the drain region 106 are formed so as to be opposite each other in the gate length direction (the direction of length of the gate electrode 104). The channel region 107 is formed between the source region 105 and the drain region 106. The gate width of the gate electrode 104 is greater than the length of the channel region 107 in the gate width direction (in the direction of width of the gate electrode 104), and both ends of the gate electrode 104 extend over the device isolation portion 102.

The channel region 107 is located inwardly of the gate electrode 104, when viewed in the stacking direction. The channel region 107 includes a central region 107a and protruding regions 107b and 107c. When viewed in the stacking direction, the central region 107a has a rectangular shape extending from a side end of the source region 105 to a side end of the drain region 106 in the gate length direction. When viewed in the stacking direction, the protruding region 107b protrudes from one side end of the central region 107a in the gate width direction, while the protruding region 107c protrudes from the other side end of the central region 107a in the gate width direction.

The source region 105 and the drain region 106 have the same conductivity type. The conductivity type of the channel region 107 is opposite to that of the source and drain regions 105 and 106. For example, when the source and drain regions 105 and 106 are n-type semiconductor layers, the channel region 107 is a p-type semiconductor layer.

Although not shown, wiring is formed in the gate electrode 104, the source region 105, and the drain region 106 via contacts. This wiring allows the semiconductor device shown in FIG. 1A to operate as a transistor in a semiconductor integrated circuit.

Now, a description will be made of subchannels which are formed in the channel region 107 shown in FIG. 1. The subchannels are channels having a lower threshold voltage than a channel formed in the central region 107a and occurring in parts of the channel region 107 located near the boundary with the device isolation portion 102.

In the channel region 107 shown in FIG. 1, one of the subchannels is formed along the periphery of the protruding region 107b. The length of the subchannel in the protruding region 107b thus becomes greater as compared with a case in which the protruding region 107b is not formed (i.e., in a case in which one side end of the central region 107a is in contact with the device isolation portion 102). This greater length causes the resistance of the subchannel to increase to thereby reduce the amount of electric charge passing thorough the subchannel, as compared with the case where the protruding region 107b is not formed. The same holds true for the protruding region 107c, and the amount of electric charge passing thorough the subchannel therein is reduced. It is thus possible to reduce off-leakage current.

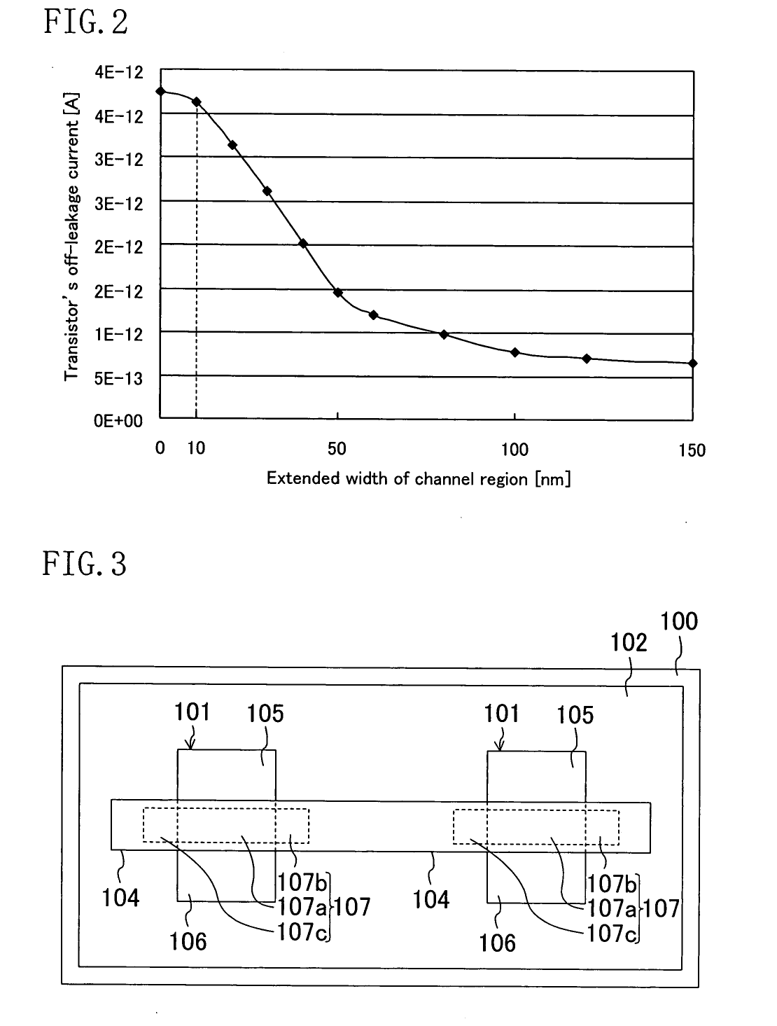

FIG. 2 shows results of 3-D device simulation of relationship between the extended width of the channel region 107 (i.e., the protrusion length of the protruding regions 107b and 107c) and the off-leakage current. The simulation was performed for a transistor having a gate length of 0.1 μm and a gate width (a source width, a drain width) of 0.16 μm. In the simulation results shown in FIG. 2, when the protrusion length of the protruding regions is equal to or greater than 10 nm, the off-leakage current is substantially reduced. The lower limit of the protrusion length of the protruding regions varies depending on the gate length, the gate width, and other parameters in the semiconductor device.

As described above, hump characteristics are suppressed. Furthermore, when viewed in the stacking direction, the channel region is located inwardly of the gate electrode. Thus, unlike in the conventional case (shown in Patent Document 1), it is not necessary to cover and protect a specific region, allowing the semiconductor device to be fabricated in an easier manner as compared with the conventional case. That is, in forming the device isolation portion 102, it is sufficient to pattern the device active portion in such a manner that the protruding regions can be formed in a later step, thereby eliminating the need for adding another step (e.g., a covering step for forming a semiconductor region). To be specific, it is sufficient to pattern the device active portion in such a manner that, in the gate width direction, the length of the part of the device active portion that is to be the channel region is greater than the length of the parts thereof that are to be the source and drain regions 105 and 106 and is smaller than the length (the gate width) of the gate electrode that is to be formed later.

Also, in the conventional case (shown in Patent Document 1), since semiconductor regions are formed in parts of the semiconductor substrate that correspond in position to both ends of the gate electrode, there are many restrictions imposed on the layout. For example, in a layout for an inverter circuit or the like, a single common gate electrode is disposed across a plurality of transistors (device active portions). In such a layout, it is not possible to form semiconductor regions for the respective device active portions as in the conventional case. In contrast, as shown in FIG. 3, in the semiconductor device of this embodiment, a single common gate electrode can be disposed over a plurality of device active portions for formation of an inverter circuit, and the number of restrictions imposed on the layout is thus reduced as compared with the conventional case.

(Modified Examples of the Device Active Portion)

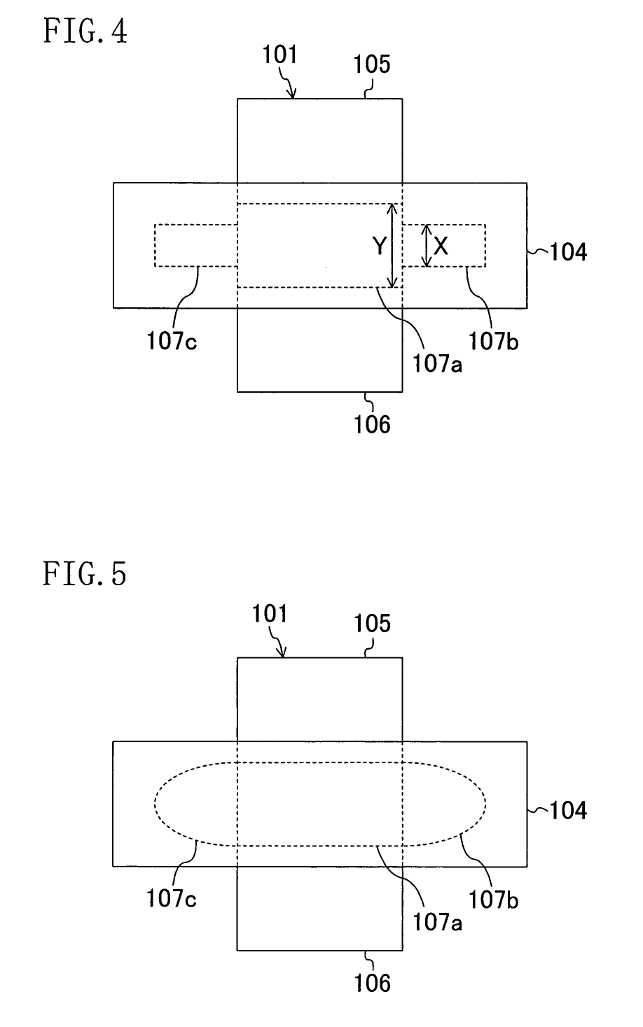

Next, with reference to FIGS. 4 to 12, modified examples of the device active portion 101 shown in FIG. 1 will be described in detail.

(1) The Base End Width of the Protruding Region

As shown in FIG. 4, the width X of the base end of the protruding region 107b may be smaller than the width Y of one side end of the central region 107a. That is, if the base end width of the protruding region is equal to or smaller than the width of the one side end of the central region, off-leakage current can be reduced.

(2) Shape of the Protruding Region

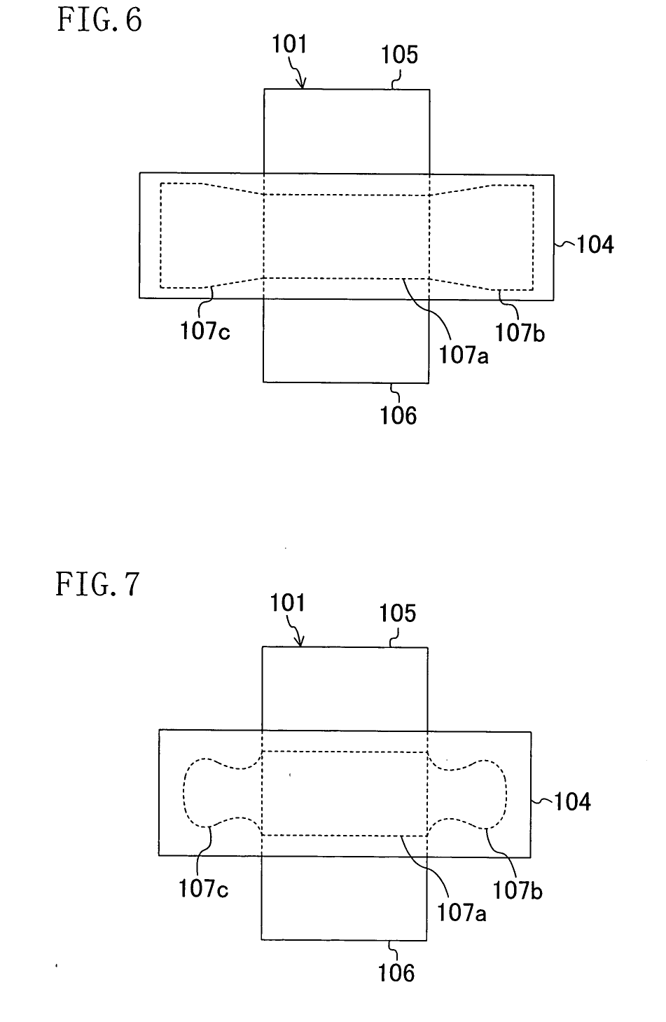

As shown in FIG. 5, the protruding region 107b may have a shape in which the protrusion width thereof is gradually reduced in the direction going from the base end thereof to the distal end thereof. Alternatively, as shown in FIG. 6, the protruding region 107b may have an opposite shape in which the protrusion width thereof is gradually increased in the direction going from the base end thereof to the distal end thereof. Furthermore, the distal end portion of the protruding region 107b may be expanded as shown in FIG. 7. That is, the protruding region 107b may have a shape in which the protrusion width thereof continuously changes in the direction in which the protruding region 107b protrudes. It should be noted that the protruding region 107b typically has a rounded shape as shown in FIG. 5.

(3) Shape of the Side End Portions of the Source and Drain Regions.

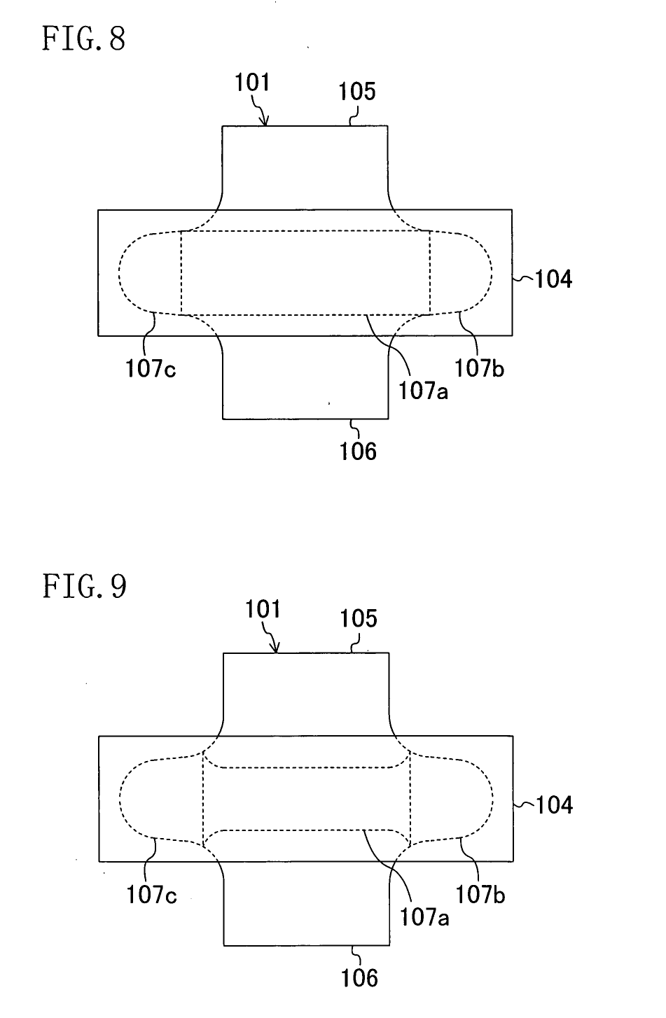

As shown in FIG. 8, the source region 105 may be formed so that the width of a side end portion thereof is gradually increased in the direction toward the central region 107a. Also, as shown in FIG. 9, both ends of the side end portion of the source region 105 that is in contact with the channel region (the central region 107a and the protruding regions 107b and 107c) may be rounded. The same holds true for the drain region 106.

(4) Extended Region

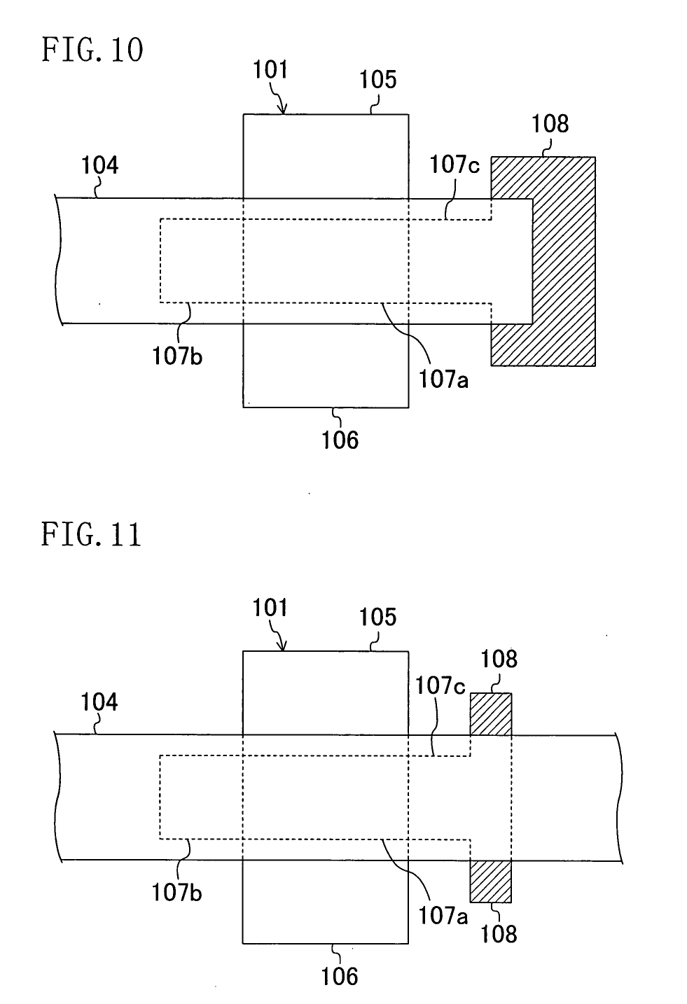

As shown in FIG. 10, the device active portion 101 may includes an extended region 108 which extends from the edge of the distal end portion of the protruding region 107c. That is, part of the channel region may extend beyond the gate electrode 104. The extended region 108 is a part of the channel region that extends outwardly of the gate electrode 104 when viewed in the stacking direction. The conductivity type of the extended region 108 may be the same as or different from that of the protruding region 107c. When the conductivity type of the extended region 108 is the same as that of the protruding region 107c, the extended region 108 may be used as a substrate contact region.

If the extended region 108 is formed in a different position determined with consideration, the layout shown in FIG. 3 can also be realized. For example, as in the device active portion 101 shown in the left-hand part of FIG. 3, if the end portion of the gate electrode 104 is not present over the protruding region 107c, the extended region 108 may be formed as shown in FIG. 11.

(5) Recessed Regions

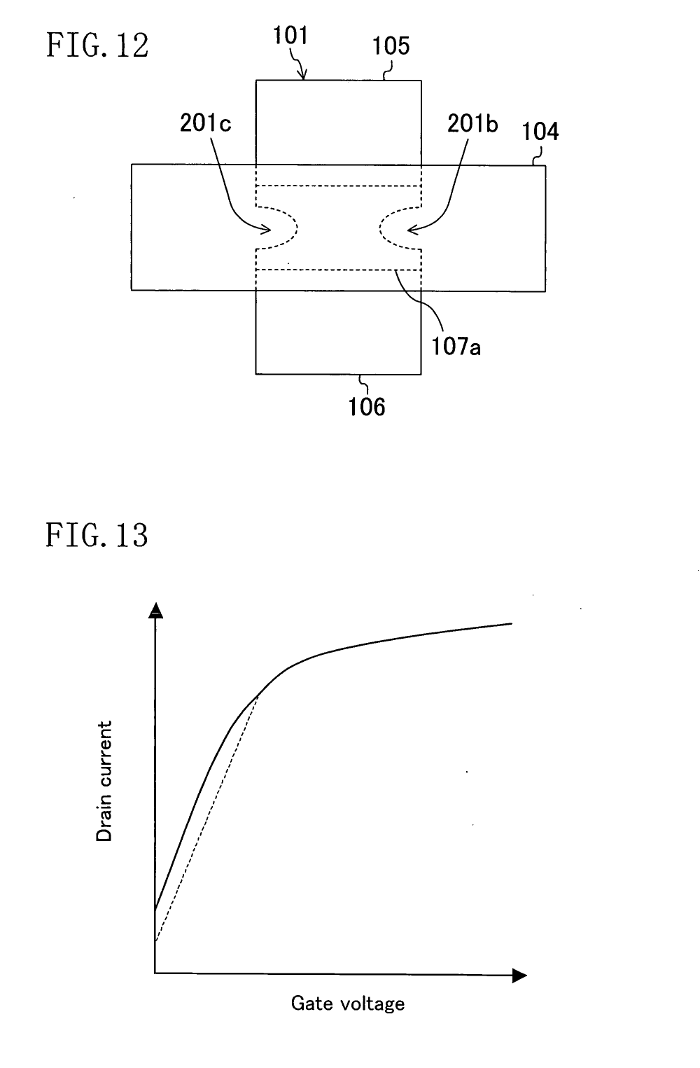

As shown in FIG. 12, instead of the protruding regions, recessed regions 201b and 201c may be formed at both ends of the central region 107a. The recessed region 201b recesses from one side end of the central region 107a toward the inside of the central region in the gate width direction. The recessed region 201c recesses from the other side end of the central region toward the inside of the central region in the gate width direction. In this case, since a subchannel is formed along the periphery of the recessed region 201b, off-leakage current can be reduced further as compared with cases in which the recessed region 201b is not formed. The same holds true for the recessed region 201c.

In the above description, if at least either the protruding region 107b or 107c is formed, the effect of reducing off-leakage current is achieved. Likewise, if at least either the recessed region 201b or 201c is formed, the effect of reducing off-leakage current is achieved.

Furthermore, typical conventional hump-prevention methods, such as a process for rounding the cross-sectional shape of the boundary portion between the STI and the channel region, and a process for introducing impurities into the side faces of the trenches when the STI is formed, may be used together with the techniques described above.

The semiconductor device according to the present invention is effective in suppressing hump characteristics and reducing off-leakage current to thereby lower the circuit's power consumption.

What is claimed is:

1. A semiconductor device, comprising:
a semiconductor substrate;
a device active portion formed in the principal surface of the semiconductor substrate;
a device isolation portion formed in the principal surface of the semiconductor substrate so as to surround the periphery of the device active portion;
an insulating film stacked on the device active portion; and
a gate electrode stacked on the insulating film,
wherein the device active portion includes:
a source region and a drain region located opposite each other in a gate length direction, and
a channel region interposed between the source region and the drain region and exhibiting a conductivity type different from that of the source and drain regions;
the channel region includes:
a central region connecting the source and drain regions and having an approximately rectangular shape, and
a protruding region protruding from one side end of the central region in a gate width direction; and
the channel region is located inwardly of the gate electrode when viewed in the stacking direction.

2. The semiconductor device of claim 1, wherein the width of a base end of the protruding region is equal to or smaller than the width of the one side end of the central region.

3. The semiconductor device of claim 1, wherein the protrusion width of the protruding region continuously changes in the direction in which the protruding region protrudes.

4. The semiconductor device of claim 3, wherein the protrusion width of the protruding region is continuously reduced in the direction in which the protruding region protrudes.

5. The semiconductor device of claim 3, wherein the protrusion width of the protruding region is continuously increased in the direction in which the protruding region protrudes.

6. The semiconductor device of claim 1, wherein the device active portion further includes an extended region which extends from the edge of a distal end portion of the protruding region, and
the extended region extends outwardly of the gate electrode when viewed in the stacking direction.

7. The semiconductor device of claim 6, wherein the extended region has a conductivity type which is the same as that of the protruding region.

8. The semiconductor device of claim 6, wherein the extended region has a conductivity type which is different from that of the protruding region.

9. The semiconductor device of claim 1, wherein the protrusion length of the protruding region is equal to or greater than 10 nm.

10. A semiconductor device, comprising:
a semiconductor substrate;
a device active portion formed in the principal surface of the semiconductor substrate;
a device isolation portion formed in the principal surface of the semiconductor substrate so as to surround the periphery of the device active portion;
an insulating film stacked on the device active portion; and
a gate electrode stacked on the insulating film,
wherein the device active portion includes:
a source region and a drain region located opposite each other in a gate length direction, and
a channel region interposed between the source region and the drain region and exhibiting a conductivity type different from that of the source and drain regions;
the channel region includes:
a central region connecting the source and drain regions and having an approximately rectangular shape, and
a recessed region recessing from one side end of the central region toward inside the central region in a gate width direction; and
the channel region is located inwardly of the gate electrode when viewed in the stacking direction.
